(19) United States
(12) Patent Application Publication
(10) Pub. No.: US 2026/0194928 A1
(43) Pub. Date: Jul. 9, 2026

(54) Battery Monitor With Reduced Power Mode

(71) Applicant: TEXAS INSTRUMENTS INCORPORATED, Dallas, TX (US)

(72) Inventors: Bradford Hunter, Hutto, TX (US); James Halstead, Doylestown, PA (US); Xiaoqiu Huang, Dallas, TX (US)

(21) Appl. No.: 19/013,545

(22) Filed: Jan. 8, 2025

(51) Int. Cl. G05F 1/56; G01R 31/392; H02J 7/00

(52) U.S. Cl. CPC G05F 1/56; G01R 31/392; H02J 7/855

(57) ABSTRACT

An oscillator has an enable input and an oscillator output. A voltage regulator has an enable input. A logic circuit has a control input, a control output and a status output and has a counter having a clock input coupled to the oscillator output. The control output couples to the enable inputs of the oscillator and the voltage regulator. The logic circuit is configured to: in response to a first control value at the control input, assert a control signal at the control output to a first logic state to enable the oscillator, cause the counter to count, and disable the voltage regulator; and in response to the counter reaching a terminal value, set a status signal at the status output to a first logic state, and assert the control signal at the control output to a second logic state to disable the oscillator and enable the voltage regulator.

### BACKGROUND

Integrated circuits operating from batteries, or other sources of limited energy) may benefit from low power states to prolong operational life. Integrated circuits with large digital gate counts may benefit from a power gate (e.g., a power transistor) that, when off, completely shuts down power to the integrated circuit. An external condition, such as connection of battery charger, provides a wake-up signal to turn on the power gate and wake up the integrated circuit. For an integrated circuit that implements a timekeeping function such as a battery monitor, complete loss of power prevents the integrated circuit from maintaining time information.

### SUMMARY

In one example, an apparatus includes an oscillator having an oscillator control input and an oscillator output. A voltage regulator has a voltage regulator input, a voltage regulator output, and a voltage regulator control input. The voltage regulator is configured to be disabled based on the voltage regulator control input having a signal at a first logic state and to be enabled based on the signal being at a second logic state. A first logic circuit has a clock input, a first control output, a second control output, a third control output, and a status output. The clock input is coupled to the oscillator output. The first control output is coupled to the oscillator control input. The second control output is coupled to the voltage regulator control input. The first logic circuit has a counter that counts based on a clock from the oscillator received at the clock input. The first logic circuit asserts a status signal at the status output based on whether the counter expired. A second logic circuit has a status input and a voltage supply input. The status input is coupled to the status output of the first logic circuit. The voltage supply input is coupled to the voltage regulator output. The second logic circuit is configured to update a time value based on the status signal from the first logic circuit. A switch circuit has a control terminal, a first switch circuit terminal, and a second switch circuit terminal. The control terminal of the switch circuit is coupled to the third control output. The first switch circuit terminal is coupled to a power supply terminal. The second switch circuit terminal is coupled to voltage regulator input.

In another example, an apparatus includes an oscillator having an oscillator control input and an oscillator output. A voltage regulator has a voltage regulator input, a voltage regulator output, and a voltage regulator control input. The voltage regulator is configured to be disabled based on the voltage regulator control input having a signal at a first logic state and to be enabled based on the signal being at a second logic state. A first logic circuit has a clock input, a first control output, a second control output, a third control output, and a status output. The clock input is coupled to the oscillator output. The first control output is coupled to the oscillator control input. The second control output is coupled to the voltage regulator control input. The first logic circuit has a counter that counts based on a clock from the oscillator received at the clock input. The first logic circuit asserts a status signal at the status output based on whether the counter expired. A second logic circuit has a status input and a voltage supply input. The status input is coupled to the status output of the first logic circuit. The voltage supply input is coupled to the voltage regulator output. The second logic circuit is configured to update a time value based on the status signal from the first logic circuit.

In another example, an apparatus includes an oscillator having an enable input and an oscillator output. A voltage regulator has an enable input. A logic circuit has a control input, a control output and a status output. The logic circuit has a counter having a clock input coupled to the oscillator output. The control output is coupled to the enable inputs of the oscillator and the voltage regulator. The logic circuit is configured to: in response to a first control value at the control input, assert a control signal at the control output to a first logic state to enable the oscillator, cause the counter to begin counting, and disable the voltage regulator; and in response to the counter reaching a terminal value, set a status signal at the status output to a first logic state, and assert the control signal at the control output to a second logic state to disable the oscillator and to enable the voltage regulator.

In yet another example, an apparatus includes a microcontroller having a status input. The microcontroller is configured to: upon powering on, determine that a logic state at the status input is at a first logic state; and update a time value in response to determining that the status input is at the first logic state.

In a further example, a method includes transitioning a battery monitor to a first power state and enabling an oscillator to produce a clock. The method also includes determining expiration of a time period based on the clock, transitioning the battery monitor to a second power state, in which the battery monitor consumes more power than in the first power state, updating, by a logic circuit, a time value in a non-volatile memory; and transitioning the battery monitor back to the first power state.

### BRIEF DESCRIPTION OF THE DRAWINGS

FIG. 1 is a block diagram of a battery monitor, in an example.

FIG. 2 is a schematic diagram of a logic circuit included in the battery monitor of FIG. 1, in an example.

FIG. 3 is a timing diagram illustrating the operation of the logic circuit of FIG. 2, in an example.

FIG. 4 is a flow chart illustrating the operation of the battery monitor, in an example.

### DETAILED DESCRIPTION

The same reference numbers or other reference designators are used in the drawings to designate the same or similar (either by function and/or structure) features.

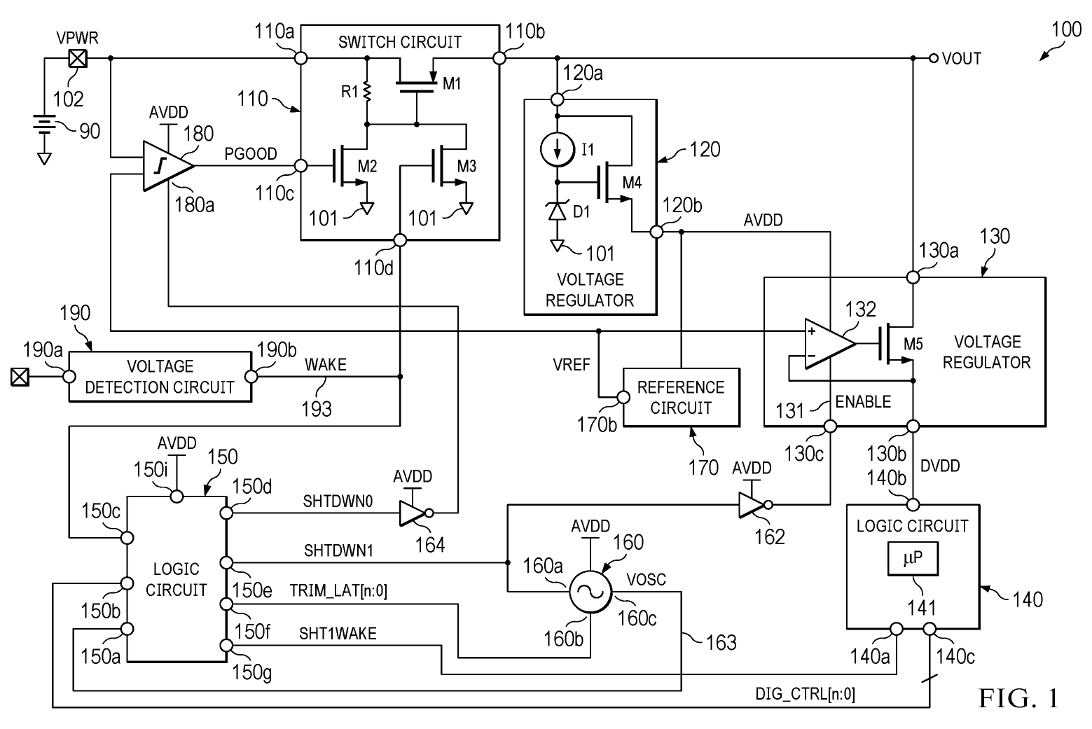

FIG. 1 is a schematic diagram of a battery monitor 100, in an example. A battery 90 is coupled to an input terminal 102 of battery monitor 100. Battery monitor 100 determines the status of battery 90 such as the age of the battery, the state of charge of the battery, and the temperature of the battery. Battery monitor 100 includes switch circuit 110, voltage regulators 120 and 130, logic circuits 140 and 150, an oscillator 160, inverters 162 and 164, a reference circuit 170, a comparator 180, and a voltage detection circuit 190. In one example, all of the components shown in FIG. 1, except battery 90, are part of a single device (e.g., an integrated circuit, IC). In some examples, some of the components of FIG. 1 are fabricated on one IC and other components are fabricated on another IC, and the multiple ICs are packaged together as one device.

Switch circuit 110 includes switch terminals 110a and 110b and control terminals 110c and 110d. Switch circuit 110 includes transistors M1, M2, and M3 and resistor R1. In this example, transistor M1 is a p-channel field effect transistor (PFET), and transistors M2 and M3 are n-channel field effect transistors (NFETs). The source of transistor M1 and one terminal of resistor R1 are coupled to switch terminal 110a, which receives an input voltage VPWR from battery 90. The gate of transistor M1 and drains of transistors M2 and M3 are coupled to the other terminal of resistor R1. The drain of transistor M1 is coupled to switch terminal 110b, which provides an output voltage VOUT when transistor M1 is on. Control terminal 110c is coupled to the gate of transistor M2, and control terminal 110d is coupled to the gate of transistor M3. The sources of transistors M2 and M3 are coupled to a supply terminal 101 (e.g., ground). When either or both of transistors M2 and M3 are on, the gate of transistor M1 at least partially discharges to thereby turn on transistor M1. With transistor M1 on, output voltage VOUT will be approximately equal to the battery voltage (VPWR).

Voltage regulator 120 includes an input 120a and an output 120b. Input 120a is coupled to switch terminal 110b and receives voltage VOUT. Voltage regulator 120 produces a voltage AVDD at output 120b. In the example of FIG. 1, voltage regulator 120 includes a current source I1, a Zener diode D1, and a transistor M4 (e.g., an NFET). Input 120a is coupled to current source I1 and the drain of transistor M4. The source of transistor M4 is coupled to output 120b. The gate of transistor M4 is coupled to the cathode of Zener diode D1 and current source I1. The anode of Zener diode D1 is coupled to the supply terminal 101. Current source I1 provides a bias current for Zener diode D1, and Zener diode D1 clamps the gate voltage of transistor M4. The output voltage AVDD from voltage regulator 120 is approximately equal to the gate voltage of transistor M4 less M4’s threshold voltage. While transistor M1 is on, voltage regulator 120 produces voltage AVDD, which is provided to voltage regulator 130, logic circuit 150, oscillator 160, inverters 162 and 164, reference circuit 170, and comparator 180.

Voltage regulator 130 includes a voltage regulator input 130a, a voltage regulator output 130b, and a voltage regulator control input 130c. Voltage regulator input 130a is coupled to output 120b of voltage regulator 120 and receives voltage AVDD. Through the voltage regulator control input 130c, voltage regulator 130 can be enabled or disabled. A signal ENABLE 131 is provided to the voltage regulator control input 130c. In one example, ENABLE 131 being logic high enables voltage regulator 130 causing voltage regulator 130 to produce voltage DVDD at voltage regulator output 130b. The ENABLE 131 being logic low disables voltage regulator 130 precluding voltage regulator 130 from generating voltage DVDD.

Voltage regulator 130 includes an operational amplifier 132 and a transistor M5 (e.g., an NFET). Voltage regulator input 130a is coupled to the drain of transistor M5. The negative (-) input of operational amplifier 132 is coupled to the source of transistor M5 and to voltage regulator output 130b. Reference circuit 170 (e.g., a bandgap reference circuit) produces a reference voltage VREF at its output 170b, which is coupled to the positive (+) input of operational amplifier 132. In the example of FIG. 1, the negative input of operational amplifier 132 has a voltage which is approximately equal to VREF, and accordingly, the voltage DVDD at the voltage regulator output 130b is approximately equal to VREF.

Voltage regulator control input 130c is coupled to operational amplifier 132. When the enable signal 131 is logic high at voltage regulator control input 130c, operational amplifier 132 is powered on (enabled) and voltage regulator 130 produces voltage DVDD. By contrast, when the enable signal 131 is logic low, operational amplifier 132 is powered off (disabled) thereby precluding voltage regulator 130 from producing voltage DVDD.

Logic circuit 140 may include a microcontroller 141 which executes machine instructions. Logic circuit 140 may include other logic circuits as well including, for example, logic gates, flip-flops, etc. Logic circuit 140 has a status input 140a, a power input 140b, and a control output 140c. When voltage regulator 130 is enabled, logic circuit 140 receives its operating voltage DVDD from voltage regulator 130 at its power input 140b. When the enable signal 131 is logic low, voltage regulator 130 is enabled and produces output voltage DVDD which powers on logic circuit 140. When the enable signal 131 is logic low, voltage regulator 130 is disabled thereby turning power off to logic circuit 140.

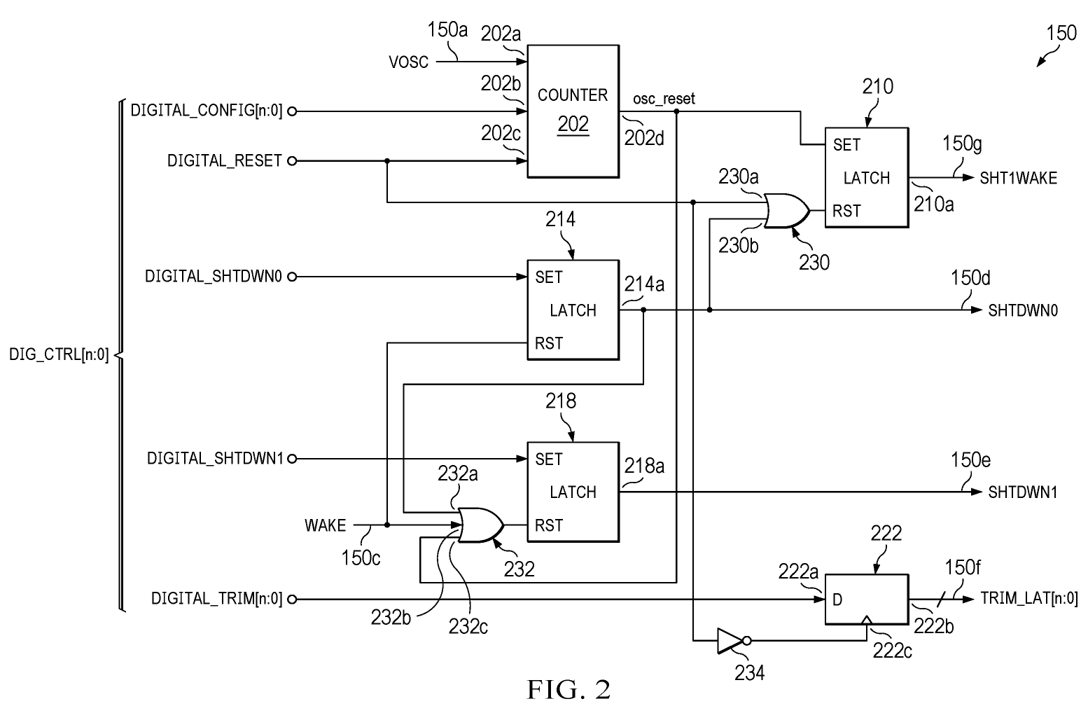

Logic circuit 150 has a clock input 150a, control inputs 150b and 150c, control outputs 150d, 150e, and 150f, and a status output 150g. An example of logic circuit 150 is shown in FIG. 2 and described below. Logic circuit 150 receives voltage AVDD as its operating power at a power input 150i and, accordingly, remains powered on even if voltage regulator 130 is disabled. In general, logic circuit 150 consumes less power than logic circuit 140. Oscillator 160 has an enable input 160a, a trim input 160b, and output 160c. When enabled, oscillator 160 produces an output clock VOSC 163 at its output 160c. The frequency of clock VOSC 163 is relatively low so that oscillator 160 consumes relatively little power. In one example, the frequency of clock VOSC is between 10 Hz and 100 KHz. In a specific example, the frequency is 1 KHz. The output 160c of oscillator 160 is coupled to the clock input 150a of logic circuit 150.

Control output 150d of logic circuit 150 is coupled to an input of inverter 164 and provides a signal SHTDWN0 to the inverter 164. Control output 150e of logic circuit 150 is coupled to the enable input 160a of oscillator 160 and to an input of inverter 162 and provides a signal SHTDWN1 to inverter 162 and to the enable input 160a of the oscillator. The output of inverter 162 is coupled to the voltage regulator control input 130c. Accordingly, the logic state of signal SHTDWN1 determines whether voltage regular 130 is enabled (when SHTDWN1=1) or disabled (when SHTDWN1=0).

Status output 150g of logic circuit 150 is coupled to the status input 140a of logic circuit 140 and provides a status signal SHT1WAKE to logic circuit 140. The control output 140c of logic circuit 140 is coupled to the control input 150b of logic circuit 150. In one example, control output 140c is an n-bit (e.g., 8-bit) digital value (DIG_CTRL[n:0]) over which any of multiple parameters or commands can be communicated from logic circuit 140 to logic circuit 150. For example, logic circuit 140 may provide a trim value via control output 140c to logic circuit 150. The trim value may be determined apriori and loaded into non-volatile memory in logic circuit 140 to control the frequency of clock VOSC. Logic circuit 150 relays the trim value, TRIM_LAT, to oscillator 160 to thereby cause oscillator 160 to adjust the frequency of the clock VOSC produced by the oscillator. In another example, logic circuit 140 can provide a command via control output 140c to logic circuit 150 for logic circuit 150 to implement any of multiple lower power states, described below.

When enabled, comparator 180 compares voltage VPWR to voltage VREF to determine if the voltage from battery 90 is above (or equal to) or below VREF. Comparator 180 generates an output signal PGOOD at its output at a logic high level if VPWR is greater than VREF and at a logic low level if VPWR is less than VREF. The output of comparator 180 is coupled to the gate of transistor M2. In response to PGOOD being logic high, transistor M2 turns on thereby turning on transistor M1. In response to PGOOD being logic low (which also occurs when comparator 180 is disabled), transistor M2 turns off. The output of inverter 164 is coupled to an enable input 180a of comparator 180. In response to the signal SHTDWN0 from control output 150d of logic circuit 150 being logic high, inverter 164 forces its output signal logic low thereby disabling comparator 180. In response to the signal SHTDWN0 from control output 150d of logic circuit 150 being logic low, the output signal from inverter 164 will be logic high thereby enabling comparator 180.

Voltage detection circuit 190 has an input 190a and an output 190b. Input 190a can be coupled to, for example, a terminal of charger for charging battery 90. Voltage detection circuit 190 detects the presence or absence of a signal at input 190a. In response to detection of a signal at its input 190a, voltage detection circuit 190 asserts (e.g., logic high) an output signal WAKE 193 at its output 190b. If a signal is not detected at input 190a, voltage detection circuit 190 does not assert output signal WAKE 193 at its output 190b (e.g., WAKE 193 is logic low). In one example, input 190a is coupled to a power input to a circuit within the voltage detection circuit. In response to a signal being present at input 190a, such circuit powers on forces the signal WAKE 193 to a logic high state.

Output 190b of voltage detection circuit 190 is coupled to control input 150c of logic circuit 150 and to the gate of transistor M3. Accordingly, in response to detection of a signal at input 190a, voltage detection circuit 190 asserts WAKE 193 to a logic high level, which causes transistor M3 to turn on. With transistor M3 being on, transistor M1 turns on. Further, logic circuit 150 detects when WAKE 193 is asserted high. The functionality of logic circuit 140 in response to signal WAKE 193 being logic high is described below.

The output 120b of voltage regulator 120 provides voltage AVDD for logic circuit 150, oscillator 160, inverters 162 and 164, reference circuit 170, and comparator 180. As noted above, when enabled, voltage regulator 130 provides voltage DVDD for powering logic circuit 140. Battery monitor 100 implements multiple power states. In a wake state, transistor M1 is on and voltage regulator 120 generates voltage AVDD, and logic circuit 150, inverters 162 and 164, reference circuit 170, and comparator 180 are powered on, and voltage regulator 130 is enabled and powers logic circuit 140. Oscillator 160 also receives voltage AVDD and is disabled in the wake state and enabled when signal SHTDWN1 is logic high.

Battery monitor 100 also implements at least two lower power states (lower power than the wake state)—shutdown state 0 and shutdown state 1. Battery monitor 100 consumes less power in shutdown state 0 than in shutdown state 1. In shutdown state 1 but not in shutdown state 0, battery monitor 100 is able to determine the age of the battery. Logic circuit 140 can issue a command via control output 140c to logic circuit 150 to transition from the wake state to the shutdown state 0 (e.g., by setting signal SHTDWN0 logic high) which inverter 162 inverts to a logic low state. The output of inverter 162 being logic low disables comparator 180, which turns off transistor M2 thereby also turning off transistor M1. With transistor M1 off, voltage regulators 120 and 130 do not produce their output voltages AVDD and DVDD, respectively, and logic circuits 140 and 150, oscillator 160, inverters 162 and 164, reference circuit 170, and comparator 180 turn off. Voltage detection circuit 190 also is off but will power on when a signal is present at its input 190a.

An external event, such as connecting the system including battery 90 and battery monitor 100 to a charger, can wake up battery monitor 100 from shutdown state 0. In response to the signal WAKE 193 being logic high, transistor M3 turns on thereby also turning on transistor M1. With transistor M1 on, voltage regulator 120 produces voltage AVDD thereby powering on logic circuits 140 and 150, oscillator 160, inverters 162 and 164, reference circuit 170, and comparator 180. Logic circuit 150 responds to a logic high assertion of signal WAKE 193 by forcing signals SHTDWN0 and SHTDWN1 to logic low states thereby ensuring that both the shutdown state 0 and the shutdown state 1 are disabled. Voltage regulator 130 is thereby enabled which powers on logic circuit 140.

Waking up from shutdown state 0 returns battery monitor 100 to the wake state. During the wake state, battery monitor 100 can monitor the status of battery 90 such as determining its age and health. However, during shutdown state 0, battery monitor 100 is unable to keep track of elapsed time. Accordingly, when battery monitor 100 returns to the wake state from shutdown state 0, battery monitor 100 is unable to ascertain how long it was in shutdown state 0.

The use of shutdown state 1 permits battery monitor 100 to implement a lower power state to save battery power while still being able to keep track of elapsed time. While in the wake state, logic circuit 140 can issue a command via control output 140c to logic circuit 150 (e.g., by setting signal SHTDWN1 logic high, which causes logic circuit 150 to disable voltage regulator 130 and enable oscillator 160. In shutdown state 1, switch M1 remains on, voltage regulator 120 produces output voltage AVDD, and logic circuits 140 and 150, oscillator 160, inverters 162 and 164, reference circuit 170, and comparator 180 are on. In shutdown state 1, voltage regulator 130 is disabled and, accordingly, logic circuit 140 is off. A counter (described below) in logic circuit 150 counts pulses of clock VOSC 163 from oscillator 160. When the counter expires (which may be a value programmed by logic circuit 140 before logic circuit 140 issues the command to logic circuit 150 to enter shutdown state 1), logic circuit 140 responds by transitioning from shutdown state 1 to the wake state. Logic circuit 140 also sets the logic level of status signal SHTWAKE to, for example, logic high. In the wake state, voltage regulator 130 is enabled and logic circuit 140 powers on. Logic circuit 140 (e.g., its microcontroller 141) determines the logic state of status signal SHTWAKE. In one example, a logic high for status signal SHTWAKE means that logic circuit 140 has powered on following a defined time period implemented by oscillator 160 and the counter within logic circuit 150. Logic circuit 140 updates a time value in non-volatile memory to account for the time period implemented by the counter. For example, logic circuit 140 may increment a value in non-volatile memory to correspond to the elapsed time that passed during shutdown state 1. However, if the wake state was initiated by voltage detection circuit 190 upon detecting a signal at input 190a, logic circuit 140 powers on but status signal SHTWAKE will be a logic 0, and logic circuit 140 may not update its time value (e.g., foregoes updating the time value) because the length of time that elapsed before voltage detection circuit 190 detects a signal at input 190a is indeterminate.

The use of shutdown state 1 is usable during, for example, shipment of a product containing battery 90 and battery monitor 100. During such shipment, battery monitor 100 toggles back and forth between the wake state and shutdown state 1, being, for example, in shutdown state 1 longer than in the wake state to save power. Battery monitor 100 transitions after each defined time period (via the counter in logic circuit 150) to the wake state so that logic circuit 140 can ascertain the health and status of battery 90 and update the time value to keep track of the age of battery 90.

FIG. 2 is schematic diagram of an example of logic circuit 150. In this example, logic circuit 150 includes a counter 202, latches 210, 214, 218 and 222, OR gates 230 and 232, and inverter 234. Counter 202 has inputs 202a, 202b, and 202c and an output 202d. Clock input 150a is coupled to input 202a and provides clock signal VOSC from oscillator 160 to counter 202 when oscillator 160 is enabled. The digital value DIG_CTRL[n:0] includes bits corresponding to each of the DIGITAL_CONFIG, DIGITAL_RESET, DIGITAL_SHTDWN0, DIGITAL_SHTDWN1, and DIGITAL_TRIM signals shown in FIG. 2. DIGITAL_CONFIG is provided to input 202b, and DIGITAL_RESET is provided to input 202c. DIGITAL_SHTDWN0 and DIGITAL_SHTDWN1 are provided to the set inputs of latches 214 and 218, respectively. Logic circuit 140 generates reset signal DIGITAL_RESET to reset the counter. Resetting logic circuit 150 occurs prior to entering shutdown state 1 and causes registers in logic 150 to be set to a known state. Logic circuit 150 can provide control bits to logic circuit 150, such as a count value to input 202b of counter 202. Counter 202 counts pulses of clock signal VOSC and asserts an output signal OSC_RESET to a, for example, logic high state when the counter reaches the programmed count value. The digital value DIG_CTRL[n:0] may also include a trim value DIGITAL_TRIM for oscillator 160.

The output 202d of counter 202 is coupled to a set input of latch 210. The output 214a of latch 214 is coupled to input 230b of OR gate 230 and the signal DIGITAL_RESET is provided to the input 230a of OR gate 230. The output signal from latch 214 is the control signal SHTDWN0. OR gate 230 logically OR’s together the output signal from latch 214 and the reset signal DIGITAL_RESET. The output of OR gate 230 is coupled to the reset (RST) input of latch 210. The output 210a of 210 is coupled to the status output 150g of logic circuit 150 and provides the status signal SHT1WAKE.

Trim value DIGITAL_TRIM is provided to the data (D) input 222a of latch 222. The DIGITAL_RESET signal is provided to an input of inverter 234, and the output of inverter 234 is coupled to a clock input 222c of latch 222. The output 222b of latch 222 is coupled to the control output 150f of logic circuit 150. A falling edge of the reset signal DIGITAL_RESET causes latch 222 to latch in the trim value to its output 222b as output trim value TRIM_LAT so that the trim value can be saved even when logic circuit 140 (which provides the trim value) is turned off upon disabling voltage regulator 130.

As explained above, logic circuit 140 can issue commands to logic circuit 150 via the value DIG_CTRL[n:0] to command logic circuit 150 to implement the shutdown state 0 or the shutdown state 1. A logic high for signal DIGITAL_SHTDOWN0 sets latch 214 forcing signal SHTDWN0 at its output 214a to a logic high level. A logic high for signal DIGITAL_SHTDOWN1 sets latch 218 forcing signal SHTDWN1 at its output 218a to a logic high level. OR gate 232 has inputs 232a, 232b, and 232c. Output 214a of latch 214 is coupled to input 232a. Output 202d of counter 202 is coupled to input 232c. Control input 150c of logic circuit 150 is coupled to input 232b. OR gate 232 logically ORs together signals SHTDWN0, OSC_RESET, and WAKE. When any of these signals are logic high, latch 218 is reset forcing signal SHTDWN1 to a logic low level thereby discontinuing the shutdown state 1 or ensuring the shutdown state 1 is not activated. When the signal WAKE 193 is logic high, which is indicative of a signal being detected at input 190a of voltage detection circuit 190, both latches 214 and 218 are reset which terminates both shutdown states 0 and 1 thereby implementing the wake state.

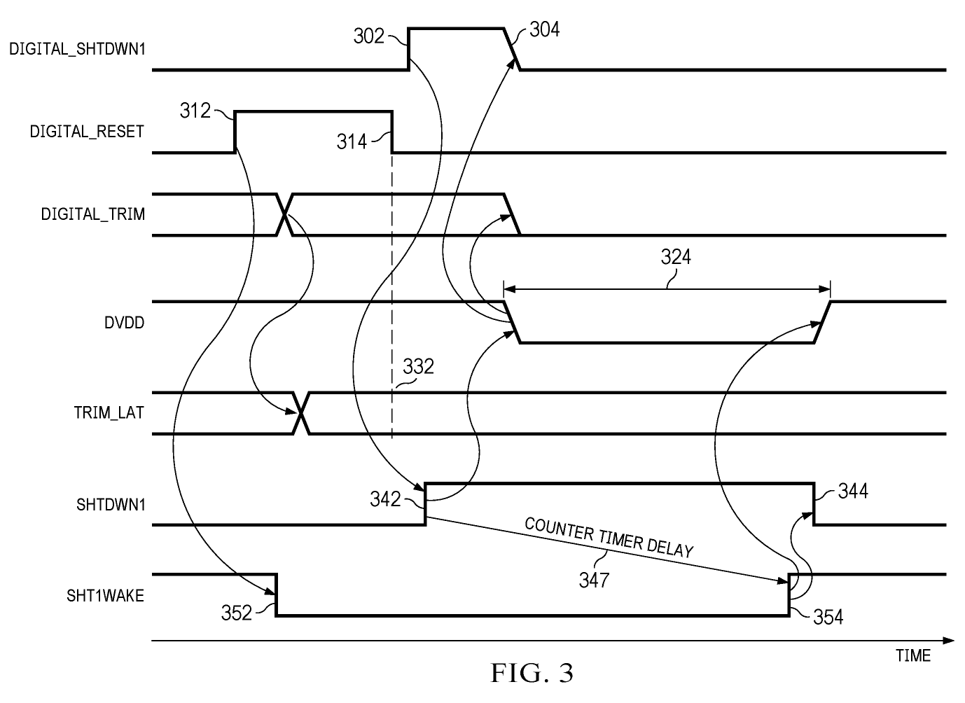

FIG. 3 is a timing diagram illustrating the operation of logic circuit 150 of FIG. 2. The timing diagram of FIG. 3 includes the signals: DIGITAL_SHTDWN1, DIGITAL_RESET, DIGITAL_TRIM, TRIM_LAT, SHTDWN1, and SHT1WAKE and voltage DVDD. Referring to FIGS. 2 and 3, logic circuit 140 may assert the signal DIGITAL_RESET to have a rising edge 312. The rising edge 312 of the signal DIGITAL_RESET resets latch 210 thereby forcing the signal SHT1WAKE to have a falling edge 352, which resets the signal SHT1WAKE so that it can be asserted to a logic high level when counter 202 subsequently expires. Logic circuit 150 may provide a trim value to logic circuit 150 while the signal DIGITAL_RESET is logic high. Further, logic circuit 140 can load counter 202 with a terminal count value (or start count value). Logic circuit 140 can then deassert the digital reset signal DIGITAL_RESET to a logic low (falling edge 314). The falling edge 314 of the signal DIGITAL_RESET clocks latch 222 at time point 332 thereby latching through the trim value from logic circuit 140 as the trim value TRIM_LAT to oscillator 160.

Logic circuit 140 then may force the signal DIGITAL_SHTDWN1 signal to a logic high level beginning with rising edge 302 to initiate the shutdown state 1. The rising edge 302 of the signal DIGITAL_SHTDWN1 signal sets latch 218 thereby forcing the signal SHTDWN1 signal to a logic high level beginning with rising edge 342.

In response to the signal SHTDWN1 being logic high, voltage regulator 130 is disabled and oscillator 160 is enabled. As a result of voltage regulator 130 being disabled, the voltage DVDD drops to approximately 0V shutting off logic circuit 140 and causing the signal DIGITAL_SHTDWN1 to become logic low as indicated by falling edge 304. Arrow 347 represents the length of time counted by counter 202 before the counter expires (e.g., 1 hour). When the counter reaches its terminal count value, the counter’s output signal OSC_RESET (FIG. 2) becomes logic high causing at least two responses to occur. First, signal OSC_RESET being logic high sets latch 210 thereby forcing the signal SHT1WAKE to a logic high level marked by rising edge 354. Second, signal OSC_RESET being logic high resets latch 218 thereby forcing the signal SHTDWN1 to a logic low level as indicated by falling edge 344. With the signal SHTDWN1 being logic low, voltage regulator 130 is enabled and voltage DVDD returns to its regulated level. Accordingly, during shutdown state 1, voltage DVDD is off during time period 324. During that time period, battery monitor 100 consumes substantially less power than during the wake state but more power than during shutdown state 0.

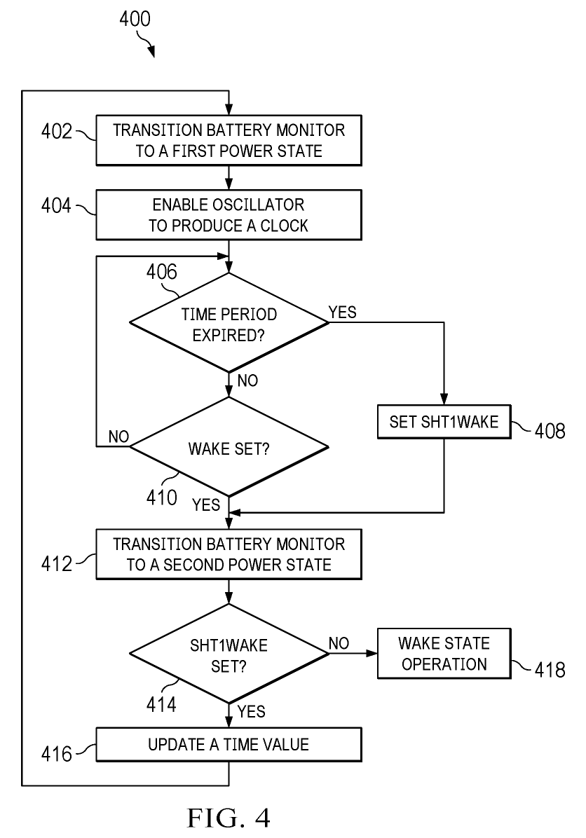

FIG. 4 is a flowchart 400 illustrating a method of operation of battery monitor 100. In the example of FIG. 4, the method includes the operation 402 of transitioning the battery monitor 100 to a first power state. In one example, the first power state is shutdown state 1. At operation 404, an oscillator, e.g., oscillator 160, is enabled to begin producing a clock (e.g., VOSC). Decision operation 406 determines whether a time period has expired. In one example, counter 202 is used to count pulses of the clock VOSC until the counter’s terminal value is reached. If the time period expires (the “yes” branch), at operation 408 the method includes setting the status signal SHT1WAKE. If the time period has not expired, then at 410, the method includes determining if the signal WAKE 193 is set. If signal WAKE 193 has not been set, control loops back to decision operation 406. Otherwise, if the time period has expired or the signal WAKE 193 has been set, at operation 412, the method includes transitioning the battery monitor 100 to a second power state. In one example, the second power state is the wake state. At decision operation 414, the method includes determining whether the status signal SHT1WAKE is set. If status signal SHT1WAKE is set (e.g., due to counter 202 having expired), then at operation 416, the method includes updating a time value. In one example, logic circuit 140 (e.g., microcontroller 141) updates the time value as described above. If the status signal SHT1WAKE is not set (e.g., due to a charger being plugged in and waking the battery charger), then at operation 418 the method includes performing normal wake state operations such as battery temperature and status monitoring.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor’s control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor’s body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

Modifications are possible in the described examples, and other examples are possible, within the scope of the claims.

What is claimed is:

1. An apparatus, comprising:
an oscillator having an oscillator control input and an oscillator output;
a voltage regulator having a voltage regulator input, a voltage regulator output, and a voltage
regulator control input, the voltage regulator configured to be disabled based on the voltage regulator control input having a signal at a first logic state and to be enabled based on the signal being at a second logic state;
a first logic circuit having a clock input, a first control output, a second control output, a third
control output, and a status output, the clock input coupled to the oscillator output, the first control output coupled to the oscillator control input, and the second control output coupled to the voltage regulator control input, the first logic circuit having a counter that counts based on a clock from the oscillator received at the clock input, and the first logic circuit asserts a status signal at the status output based on whether the counter expired;
a second logic circuit having a status input and a power input, the status input coupled to the
status output of the first logic circuit, and the power input coupled to the voltage regulator output, the second logic circuit configured to update a time value based on the status signal from the first logic circuit; and
a switch circuit having a control terminal, a first switch
circuit terminal, and a second switch circuit terminal, the control terminal of the switch circuit coupled to the third control output, the first switch circuit terminal coupled to a power supply terminal, and the second switch circuit terminal coupled to voltage regulator input.

2. The apparatus of claim 1, wherein the counter has a counter input coupled to the clock input of the first logic circuit and the counter has a counter output, and wherein the first logic circuit includes a latch having a latch input and a latch output, the latch input coupled to the counter output, and the latch output coupled to the status output.

3. The apparatus of claim 1, wherein the oscillator is configured to generate the clock having a frequency in a range of 10 Hz to 100 KHz.

4. The apparatus of claim 1, wherein the second logic circuit is configured to provide a trim value to the first logic circuit, and the first logic circuit is configured to configure the oscillator based on the trim value.

5. The apparatus of claim 1, wherein the voltage regulator is a first voltage regulator and has a first voltage regulator input, the first logic circuit has a first logic circuit power input, and the apparatus further comprises:
a second voltage regulator having a second voltage regulator input and a second voltage regulator output, the second voltage regulator input coupled to the second switch circuit terminal, and the second voltage regulator output coupled to the first voltage regulator input and to the first logic circuit power input.

6. An apparatus, comprising:
an oscillator having an oscillator control input and an oscillator output;
a voltage regulator having a voltage regulator input, a voltage regulator output, and a voltage
regulator control input, the voltage regulator configured to be disabled based on the voltage regulator control input having a signal at a first logic state and to be enabled based on the signal being at a second logic state;
a first logic circuit having a clock input, a first control output, a second control output, a third
control output, and a status output, the clock input coupled to the oscillator output, the first control output coupled to the oscillator control input, and the second control output coupled to the voltage regulator control input, the first logic circuit having a counter configured to count based on a clock from the oscillator received at the clock input, and the first logic circuit is configured to assert a status signal at the status output based on whether the counter expired; and
a second logic circuit having a status input and a power input, the status input coupled to the
status output of the first logic circuit, and the power input coupled to the voltage regulator output, the second logic circuit configured to update a time value based on the status signal from the first logic circuit.

7. The apparatus of claim 6, further comprising:
a switch circuit having a control terminal, a first switch circuit terminal, and a second switch
circuit terminal, the control terminal of the switch circuit coupled to the third control output, and the second switch circuit terminal coupled to the voltage regulator output.

8. The apparatus of claim 6, wherein the counter has a counter input coupled to the clock input of the first logic circuit and the counter has a counter output, and wherein the first logic circuit includes a latch having a latch input and a latch output, the latch input coupled to the counter output, and the latch output coupled to the status output.

9. An apparatus, comprising:
a microcontroller having a status input; and
the microcontroller configured to:
upon powering on, determine that a logic state at the status input is at a first logic state; and
update a time value in response to determining that the status input is at the first logic state.

10. The apparatus of claim 9, further comprising non-volatile memory, and the microcontroller is configured to update the time value in the non-volatile memory.

11. The apparatus of claim 9, wherein the microcontroller is configured to, if the status input is at the first logic state, output a command for the apparatus to be transitioned into a first power state after updating the time value.

12. The apparatus of claim 9, wherein the microcontroller configured to:
upon powering on, determine that the logic state at the status input is at a second logic state; and
forego updating the time value if the status input is at the second logic state.

13. An apparatus, comprising:
an oscillator having an enable input and an oscillator output;
a voltage regulator having an enable input; and
a logic circuit having a control input, a control output and a status output, the logic circuit
having a counter, the counter having a clock input coupled to the oscillator output, and the control output coupled to the enable inputs of the oscillator and the voltage regulator, the logic circuit configured to:
in response to a first control value at the control input, assert a control signal at the
control output to a first logic state to enable the oscillator, cause the counter to begin counting, and disable the voltage regulator; and
in response to the counter reaching a terminal value, set a status signal at the status
output to a first logic state, and assert the control signal at the control output to a second logic state to disable the oscillator and to enable the voltage regulator.

14. The apparatus of claim 13, wherein the voltage regulator is a first voltage regulator, the
control output is a first control output, logic circuit has a second control output and a logic circuit power input, and the apparatus comprises:
a second voltage regulator having a second voltage regulator input and a second voltage
regulator output, the second voltage regulator output coupled to the logic circuit power input; and
a switch circuit having a control input and a switch circuit terminal, the control input of the
switch circuit coupled to the second control output, and the switch circuit terminal coupled to the second voltage regulator input.

15. The apparatus of claim 13, wherein the counter has a counter output, and the logic circuit includes a latch having an input coupled to the counter output, the latch also having a latch output coupled to the status output.

16. The apparatus of claim 13, wherein the logic circuit is configured to receive a trim value at the control input and to configure the oscillator based on the trim value.

17. A method, comprising:
transitioning a battery monitor to a first power state;
enabling an oscillator to produce a clock;
determining expiration of a time period based on the clock;
transitioning the battery monitor to a second power state, the battery monitor consuming
more power in the second power state than in the first power state;
updating, by a logic circuit, a time value in a non-volatile memory; and
transitioning the battery monitor back to the first power state.

18. The method of claim 17, wherein the clock has pulses and wherein determining the expiration of the time period includes starting a counter to count the pulses.

19. The method of claim 17, further comprising:
detecting, by the battery monitor, a wake signal;
transitioning the battery monitor to the second power state;
determining, by the logic circuit whether the battery monitor entered the second power state
based on the wake signal or based on the expiration of the time period;
updating, by the logic circuit, the time value if the logic circuit determined that the battery
monitor entered the second power state based on the expiration of the time period; and
foregoing updating the time value if the logic circuit determined that the battery monitor
entered the second power state based on the wake signal.

20. The method of claim 17, wherein transitioning the battery monitor to the first power state includes turning off power to the logic circuit.
